(19) United States
(12) Patent Application Publication
(10) Pub. No.: US 2016/0013231 A1
(43) Pub. Date: Jan. 14, 2016

(54) PHASE-DIFFERENCE DETECTION PIXEL AND IMAGE SENSOR HAVING THE SAME

(71) Applicant: SAMSUNG ELECTRONICS CO., LTD., Suwon-si (KR)

(72) Inventor: Kyung-Ho LEE, Suwon-si (KR)

(21) Appl. No.: 14/614,659

(22) Filed: Feb. 5, 2015

(30) Foreign Application Priority Data
Jul. 14, 2014 (KR) 10-2014-0088506

(51) Int. Cl. H01L 27/146

(52) U.S. Cl. CPC H01L 27/14623; H01L 27/14621; H01L 27/14627; H01L 27/14645; H01L 27/14636

(57) ABSTRACT

A phase-difference detection pixel includes a photodiode layer on a substrate and including a recess, a light-blocking layer in the recess, a first insulating layer on the photodiode and light-blocking layers, a color filter layer on the first insulating layer, and a microlens layer on the color filter layer.

### CROSS-REFERENCE TO RELATED APPLICATION

Korean Patent Application No. 10-2014-0088506, filed on Jul. 14, 2014, and entitled, “Phase-Difference Detection Pixel and Image Sensor Having the Same,” is incorporated by reference herein in its entirety.

### BACKGROUND

1. Field

One or more embodiments described herein relate to a phase-difference detection pixel and an image sensor having such a pixel.

2. Description of Related Art

An image sensor converts an optical image into an electric signal. Examples of image sensors include charge coupled device (CCDs) and complementary metal oxide semiconductor device (CIS). A CIS includes an image detection pixel and a phase-difference detection pixel. An image detection pixel obtains an image signal, and a phase-difference detection pixel is provided for focusing.

### SUMMARY

In accordance with one embodiment, a phase-difference detection pixel a substrate, a photodiode layer on the substrate and partially including an upwardly open recess, a light-blocking layer in the recess, a first insulating layer on the photodiode and light-blocking layers, a color filter layer on the first insulating layer, and a microlens layer on the color filter layer. A second insulating layer may be between the light-blocking layer and an interior of the recess. The light-blocking layer and the photodiode layer may have upper surfaces at substantially a same level. The second insulating layer may be between the photodiode layer and the first insulating layer.

The photodiode layer may have an edge region that includes a light-blocking wall. A third insulating layer may be between the first insulating layer and the color filter layer; and a light-blocking wall may be along a boundary region of a pixel in the third insulating layer. The light-blocking layer may reach a boundary region of an adjacent cell. The photodiode layer may include a cell separation wall, and the light-blocking layer may reach the cell separation wall. The light-blocking layer may be deeper in the cell separation wall than in the photodiode layer. The photodiode layer may include an N-region and a P-region, and the recess may be in the P-region. The photodiode layer may include an N-region and a P-region, and the recess may reaches a portion of the N-region.

In accordance with an other embodiment, a phase-difference detection pixel includes a substrate, a metal interconnection layer on the substrate, a photodiode layer on the metal interconnection layer, a first insulating layer on the photodiode layer, a color filter layer on the first insulating layer, a light-blocking layer in the color filter layer, and a microlens layer on the color filter layer. The light-blocking layer may open in a direction toward a bottom of the color filter layer. The light-blocking layer may include a black color filter. The pixel may include a second insulating layer between the first insulating layer and the color filter layer, and a light-blocking wall along a boundary region of a pixel in the second insulating layer.

In accordance with another embodiment, an apparatus an image detection pixel, phase-difference detection pixel, and a wall between the image detection pixel and the phase-difference pixel, wherein the image detection pixel includes a first region of a photodiode layer and the phase-difference pixel includes a second region of the photodiode layer, and wherein the second region of the photodiode layer includes a light-blocking layer which is not included in the first region. The light-blocking layer may be in a recess in the second region of the photodiode layer. The wall may be between the first region and the second region of the photodiode layer. The apparatus may include an insulating layer between the light-blocking layer and the photodiode layer in the second region. A bottom surface of the light-blocking layer may be lower than an upper surface of the wall.

### BRIEF DESCRIPTION OF THE DRAWINGS

Features will become apparent to those of skill in the art by describing in detail exemplary embodiments with reference to the attached drawings in which:

FIGS. 1 to 4 illustrates an embodiment of an image sensor having a light-blocking layer in a photodiode layer;

FIGS. 5 to 8 illustrate another embodiment of an image sensor having an insulating layer;

FIGS. 9 to 12 illustrate another embodiment of an image sensor having another insulating layer;

FIGS. 13 to 15 illustrate another embodiment of an image sensor having a light-blocking wall;

FIGS. 16 to 18 illustrate another embodiment of an image sensor having an insulating layer;

FIGS. 19 to 21 illustrate another embodiment of an image sensor having another insulating layer;

FIGS. 22 to 24 illustrate another embodiment of an image sensor having an insulating layer and a light-blocking wall;

FIGS. 25 to 28 illustrate another embodiment of an image sensor including a different cell separation wall;

FIGS. 29 to 32 illustrate another embodiment of an image sensor having an insulating layer;

FIGS. 33 to 36 illustrate another embodiment of an image sensor having another insulating layer;

FIGS. 37 to 40 illustrate another embodiment of an image sensor with no cell separation wall;

FIGS. 41 to 44 illustrate another embodiment of an image sensor having an insulating layer;

FIGS. 45 to 48 illustrate another embodiment of an image sensor having another insulating layer;

FIG. 49 illustrates another embodiment of an image sensor having a light-blocking layer in a color filter layer;

FIG. 50 illustrates another embodiment of an image sensor including a different cell separation wall;

FIG. 51 illustrates another embodiment of an image sensor with no cell separation wall;

FIGS. 52 to 54 illustrate another embodiment of an image sensor having an insulating layer and a light-blocking wall;

FIGS. 55 to 57 illustrate another embodiment of an image sensor having a cell separation wall, a light-blocking wall, and an insulating layer;

FIGS. 58 and 59 illustrate an embodiment of a camera module including an image sensor in accordance with one or more of the aforementioned; and

FIG. 60 illustrates another embodiment of an image sensor.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawings, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

FIG. 1 illustrates an embodiment of an image sensor having a light-blocking layer in a photodiode layer. Referring to FIG. 1, the image sensor includes an image detection pixel A and a phase-difference detection pixel B. The image detection pixel A and the phase-difference detection pixel B may be adjacent to each other, or may be separated by one or more other elements or pixels. Additionally, or alternatively, two or more image detection pixels A may be consecutively arranged. Also, two or more phase-difference detection pixels B may be arranged to be adjacent to each other or spaced a certain distance apart.

The image detection pixel A includes a support substrate 10, an adhesive layer 20, a metal interconnection layer 30, a photodiode layer 42, a cell separation wall 41, a first insulating layer 50, a color filter layer 60, a second insulating layer 70, and a microlens layer 80. The support substrate 10 may be, for example, a semiconductor substrate, a glass substrate, or a metal substrate.

The adhesive layer 20 may attach the metal interconnection layer 30 to the support substrate 10, and may be, for example, a silicon oxide layer.

The metal interconnection layer 30 may include, for example, a plurality of metal interconnections connected to each other in an insulating layer. The insulating layer may insulate the metal interconnections, and may be, for example, a silicon oxide layer, a silicon nitride layer, or a combination thereof.

The photodiode layer 42 includes a P-region 42A in an upper portion, an N-region 42B in a center portion, and a layer 42C which corresponds to a semiconductor substrate made of, for example, silicon bulk. The photodiode layer 42 may be formed by implanting impurities into the semiconductor substrate. The P-region 42A may be formed to have an impurity concentration of P⁺, P⁺⁺, or another concentration, by implanting P-type impurities. The N-region 42B may be formed to have an impurity concentration of N⁺, N⁺⁺, or another concentration, by implanting N-type impurities. The P-region 42A and the N-region 42B may form a P-N junction. When light is irradiated onto the P-region 42A in the upper portion, electrons in the N-region 42B may increase. The P-region 42A may be formed to have a smaller vertical width than the N-region 42B. The vertical width of the P-region 42A may be greater than the vertical width of the N-region 4b in another embodiment. The photodiode layer 42 and photodiode layer 44 may be included in an overall photodiode layer 40.

The photodiode layer 42 may include the cell separation wall 41 (e.g., shallow trench isolation (STI)) at a boundary between the adjacent image detection pixel A and phase-difference detection pixel B. An upper end of the cell separation wall 41 may be higher than the N-region 42B and lower than an upper surface of the photodiode layer 42 (e.g., upper surface of P-region 42A), as illustrated in FIG. 1. The cell separation wall 41 may be formed, for example, of an insulating material such as an oxide layer or a nitride layer.

The first insulating layer 50 may be formed on the photodiode layer 40. The first insulating layer 50 may be an oxide layer, for example, a hafnium oxide layer (HfO₂).

The color filter layer 60 may be formed on the first insulating layer 50. The color filter layer 60 may form a red filter, a blue filter, and a green filter in each pixel, and may be configured in the form of an overall array.

The second insulating layer 70 may be formed on the color filter layer 60. The second insulating layer 70 may be formed as needed.

The microlens layer 80 may be formed on the color filter layer 60, and may collect light irradiated from above for transmission to the photodiode layer 42.

The phase-difference detection pixel B may include the support substrate 10, the adhesive layer 20, the metal interconnection layer 30, a photodiode layer 44, a light-blocking layer 43, the cell separation wall 41, the first insulating layer 50, the color filter layer 60, the second insulating layer 70, and the microlens layer 80.

The phase-difference detection pixel B may include the support substrate 10, the adhesive layer 20, the metal interconnection layer 30, the first insulating layer 50, the color filter layer 60, the second insulating layer 70, and the microlens layer 80, similar to the image detection pixel A. The photodiode layer 44 and the light-blocking layer 43 have a different structure from the image detection pixel A, as will be described.

The photodiode layer 44 may include a P-region 44A in an upper portion, an N-region 44B in a center portion, and a layer 44C which, for example, may be a semiconductor substrate of, e.g., silicon bulk. The photodiode layer 44 may include the cell separation wall 41 in a boundary region with an adjacent image detection pixel A. An upper end of the cell separation wall 41 may be formed to be higher than the N-region 44B and lower than an upper surface of the photodiode layer 44 (e.g., P-region 44A), as illustrated in FIG. 1.

The photodiode layer 44 may include an upwardly open recess R1. The recess R1 may be formed to have a predetermined width from an edge of the photodiode layer 44 toward the center. The recess R1 may be a trench of a predetermined shape, e.g., rectangular. A short width of the recess R1 may be in the range of 30 to 60% of a width of the photodiode layer 44. The recess R1 may be formed to have a side within the P-region at a boundary region of the photodiode layer 44.

The light-blocking layer 43 may be formed in the recess R1 of the photodiode layer 44. An insulating light-blocking material (e.g., a black color filter) may be used as the light-blocking layer 43. Alternatively, a non-insulating light-blocking material (e.g., tungsten (W)) may be used as the light-blocking layer 43.

In a manufacturing process, the recess R1 may be formed by partially etching the P-region of the photodiode layer 44. The photodiode layer 44 and the recess R1 may be filled with the light-blocking layer 43. The light-blocking layer 43 of the recess R1 and an upper portion of the photodiode layer 44 may be polished, for example, using a chemical mechanical polishing (CMP) process, until the photodiode layer 44 is exposed. Next, the first insulating layer 50 may be formed on the photodiode layer 44 and the light-blocking layer 43. The CMP process and formation of the first insulating layer 50 may be simultaneously performed in the phase-difference detection pixel B and the image detection pixel A.

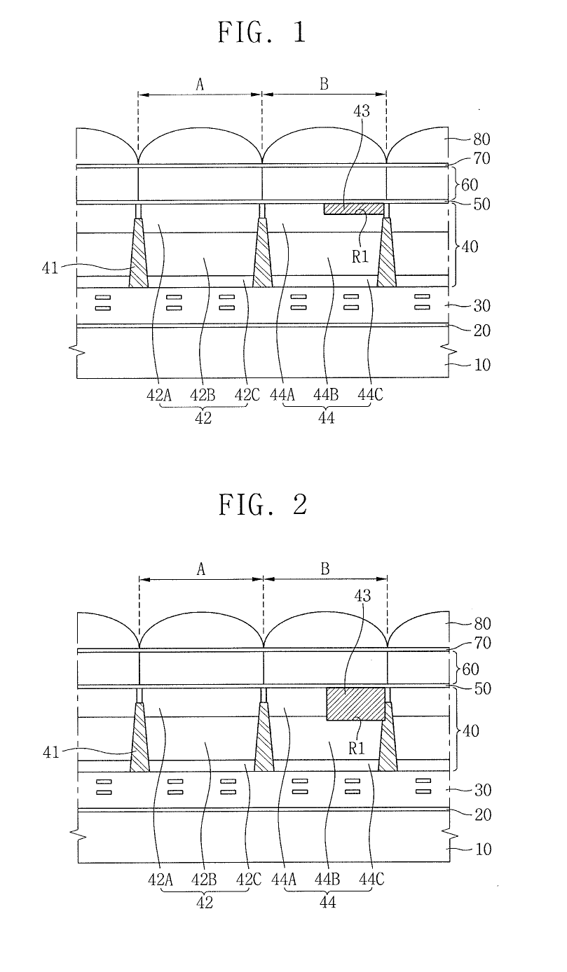

FIG. 2 illustrates another embodiment of an image sensor having a light-blocking layer in a photodiode layer. The light-blocking layer 43 is formed to be deeper in the embodiment of FIG. 2 than in the embodiment of FIG. 1.

Referring to FIG. 2, a recess R1 may be formed to pass through a P-region to reach a portion of an N-region therebelow in a photodiode layer 44. The light-blocking layer 43 filling the recess R1 may also be formed to pass through the P-region to contact the N-region. In the embodiment in FIG. 2, no insulating layer may be formed between the photodiode layer 44 and the light-blocking layer 43. In this case, an insulating light-blocking material (e.g., a black color filter) may be used as the light-blocking layer 43.

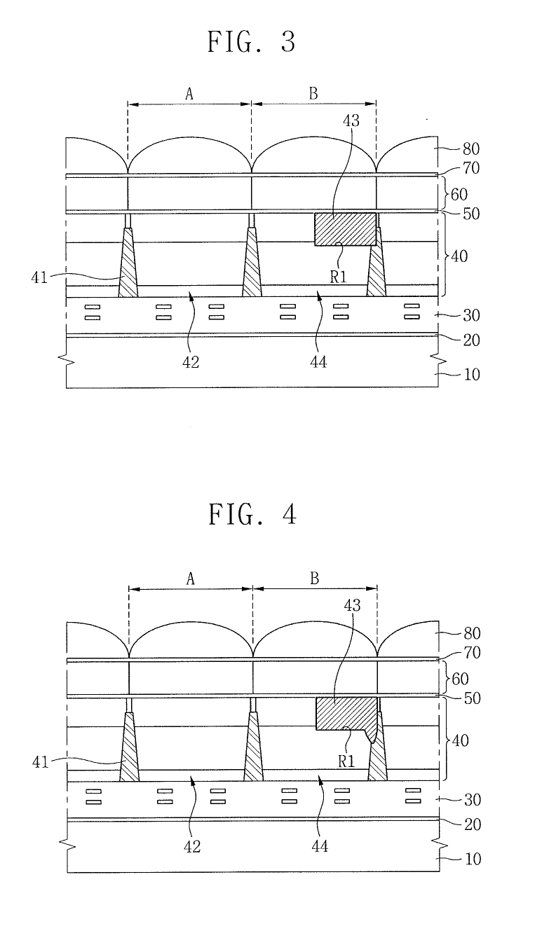

FIG. 3 illustrates another embodiment of an image sensor having a light-blocking layer in a photodiode layer. Referring to FIG. 3, compared to the embodiment in FIG. 1, a light-blocking layer 43 may be wider. Also, referring to FIG. 3, a recess R1 may be formed in such a manner that a side thereof reaches an upper portion of a cell separation wall 41 in a boundary region with a photodiode layer 44. No insulating layer may be formed between the photodiode layer 44 and the light-blocking layer 43.

Also, as illustrated in FIG. 3, when the light-blocking layer 43 reaches the N-region, an insulating light-blocking material (e.g., a black color filter) may be used as the light-blocking layer 43. When the light-blocking layer 43 is formed within a P-region, a non-insulating light-blocking material, for example, W, may be used as the light-blocking layer 43.

In the embodiment of FIG. 3, because the light-blocking layer 43 is formed to reach the upper portion of the cell separation wall 41, which is the boundary region of the photodiode layer 44, light incident to an adjacent image detection pixel A may be further blocked from being incident on a phase-difference detection pixel B.

FIG. 4 illustrates another embodiment of an image sensor having a light-blocking layer in a photodiode layer. In the embodiment in FIG. 4, a light-blocking layer 43 is deeper and wider, and also has a different shape on a cell separation wall 41, compared to the embodiment in FIG. 1.

Referring to FIG. 4, a recess R1 may be formed to have a side that reaches a cell separation wall 41 at a boundary region of a photodiode layer 44, and a bottom that reaches a portion of an N-region. The bottom is deeper in the cell separation wall 41 than in the N-region. The cell separation wall 41 may be etched more than the photodiode layer 44, by controlling an etching region and an etching selectivity while etching the photodiode layer 44. When the light-blocking layer 43 is buried deep in the cell separation wall 41, light incident to an adjacent image detection pixel A may be further effectively blocked from being incident on a phase-difference detection pixel B. Also, in the embodiment in FIG. 4, an insulating light-blocking material (e.g., for example, a black color filter) may be used as the light-blocking layer 43.

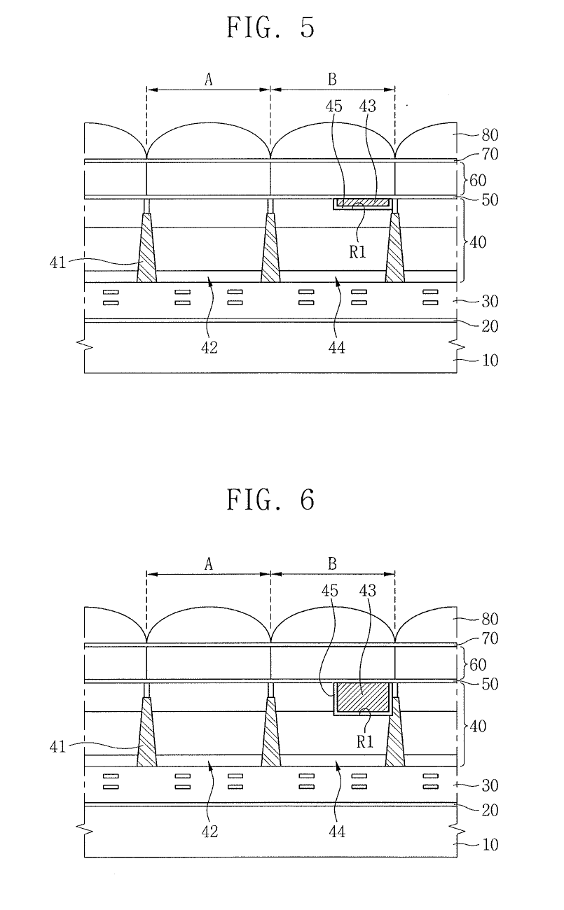

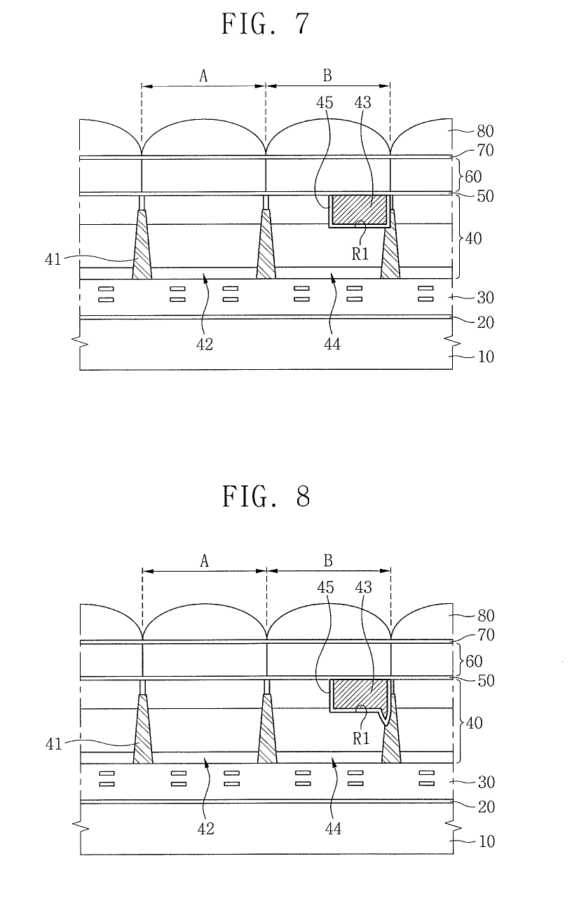

FIGS. 5 to 8 illustrate cross-sectional views illustrating another embodiment which includes image sensors. Referring to FIGS. 5 to 8, compared to the embodiments in FIGS. 1 to 4, the image sensors may further include a third insulating layer 45 between a photodiode layer 44 and a light-blocking layer 43. The third insulating layer 45 may be an oxide layer, for example, HfO₂.

In a manufacturing process, a recess R1 may be formed by partially etching the photodiode layer 44. The third insulating layer 45 may be formed in the photodiode layer 44 and the recess R1. The recess R1 may be filled with the light-blocking layer 43. The third insulating layer 45 and the light-blocking layer 43 may be polished, for example, using a CMP process until the photodiode layer 44 is exposed. Next, a first insulating layer 50 is formed on the photodiode layer 44 and the light-blocking layer 43.

When the light-blocking layer 43 is formed of an insulating light-blocking material, the third insulating layer 45 may function to enhance an insulating property. Due to the third insulating layer 45, the light-blocking layer 43 may be filled with a non-insulating light-blocking material, such as W, even when the light-blocking layer 43 reaches the N-region.

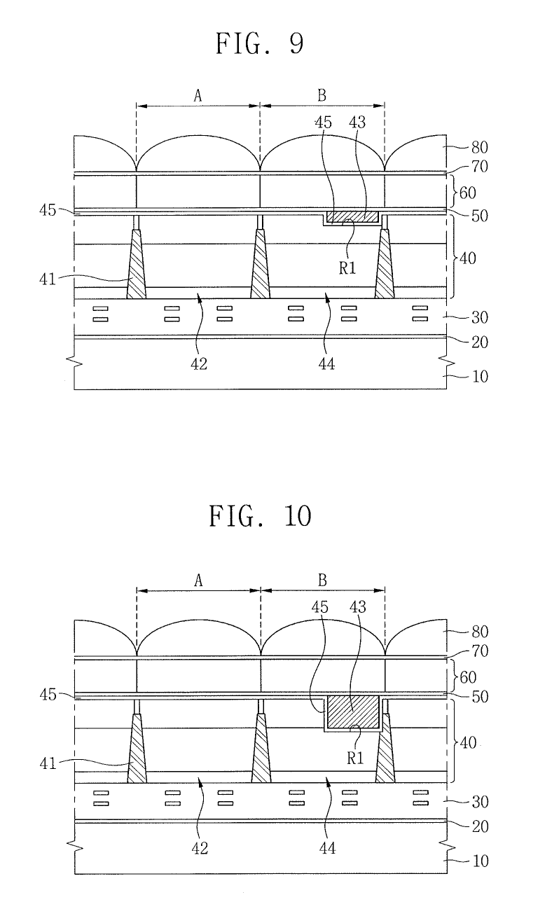

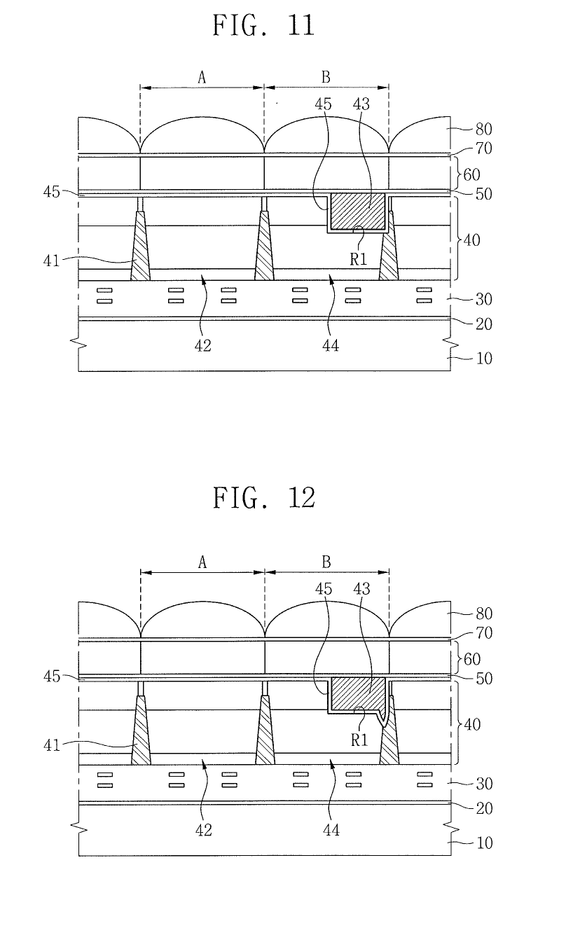

FIGS. 9 to 12 illustrate cross-sectional views of another embodiment of image sensors having another insulating layer. Referring to FIGS. 9 to 12, compared to the embodiments in FIGS. 5 to 8, image sensors may further include a third insulating layer 45 between a photodiode layer 44 and a first insulating layer 50. The third insulating layer 45 formed between the photodiode layer 44 and the first insulating layer 50 may be the same material in the same layer as the third insulating layer 45 formed between the photodiode layer 44 and the light-blocking layer 43. The third insulating layer 45 formed between the photodiode layer 44 and the light-blocking layer 43 may be an oxide layer, for example, HfO₂.

In a manufacturing process, a recess R1 may be formed by partially etching the photodiode layer 44. The third insulating layer 45 may be formed on an upper surface of the photodiode layer 44 and in the recess R1. The recess R1 in which the third insulating layer 45 is formed may be filled with a light-blocking layer 43. The third insulating layer 45 and the light-blocking layer 43 may be polished, for example, using a CMP process.

In this case, portions of the third insulating layer 45 on the photodiode layer 44 may remain. The thinner the remaining third insulating layer 45 is, the smaller a gap may be between an upper surface of the light-blocking layer 43 and an upper surface of the photodiode layer 44. Next, a first insulating layer 50 may be formed on the third insulating layer 45 and the light-blocking layer 43.

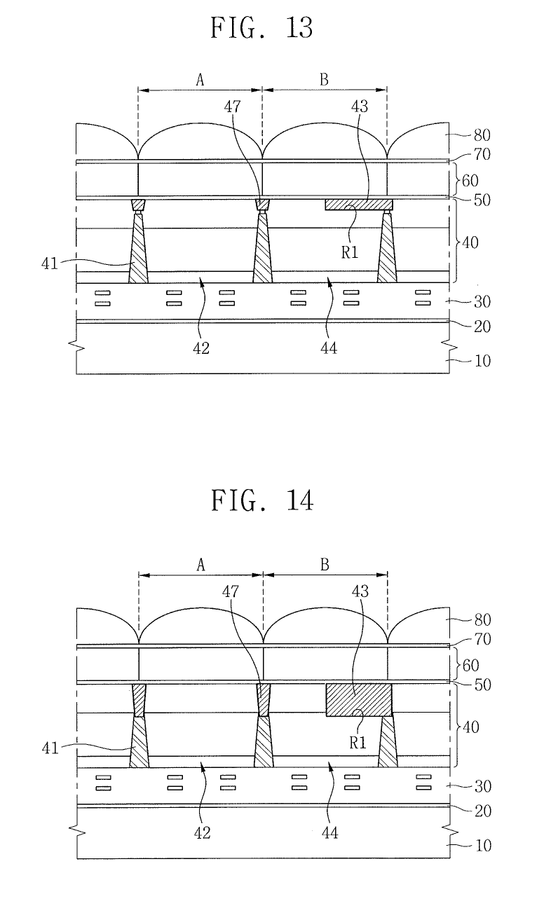

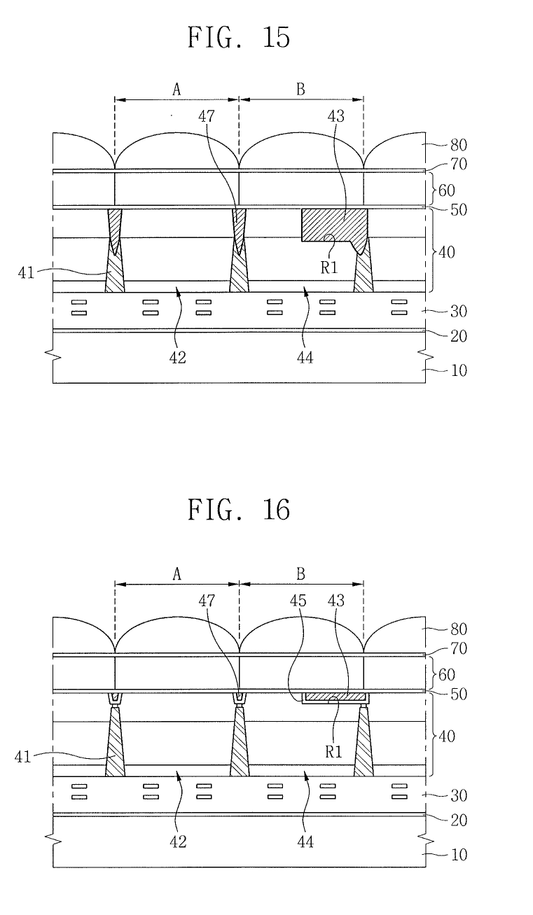

FIGS. 13 to 15 illustrate cross-sectional views of another embodiment of image sensors having a light-blocking wall. Referring to FIGS. 13 to 15, compared to the embodiments in FIGS. 1 to 4, the image sensors may further include a light-blocking wall 47 in a boundary region of the photodiode layer 44.

The light-blocking wall 47 may be formed of the same material and in the same process as the light-blocking layer 43. The light-blocking wall 47 may be formed of a material having a light-blocking or light-reflecting property. The light-blocking wall 47 may be formed of a different material and in a different process from the light-blocking layer 43. The light-blocking wall 47 may be buried in an upper surface of the photodiode layer 44 in a boundary region of the photodiode layer 44. The light-blocking wall 47 may partially block light on an adjacent image detection pixel A from being incident on a phase-difference detection pixel B.

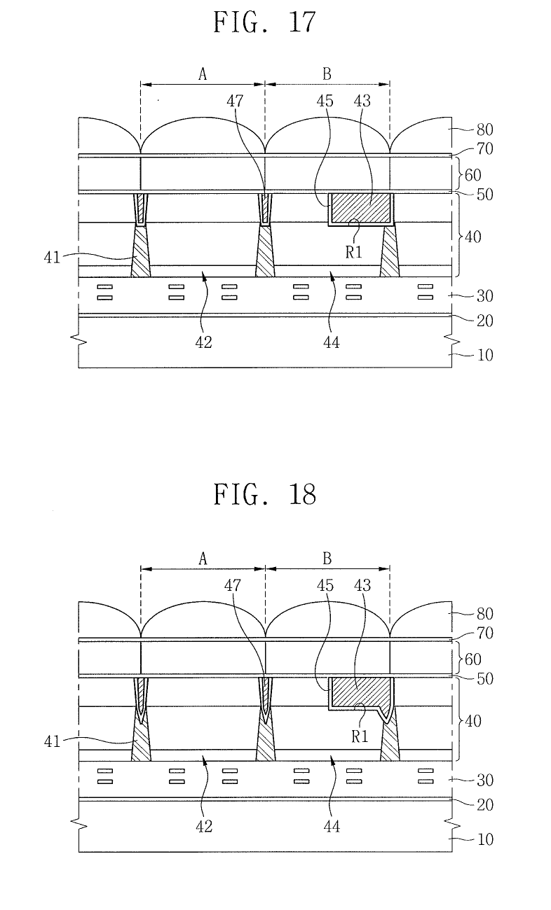

FIGS. 16 to 18 illustrate cross-sectional views of another embodiment of image sensors having an insulating layer. Referring to FIGS. 16 to 18, compared to the embodiments illustrated in FIGS. 13 to 15, the image sensor may further include a third insulating layer 45 between a photodiode layer 44 and a light-blocking layer 43. The third insulating layer 45 may be an oxide layer, for example, HfO₂. The third insulating layer 45 may be formed, for example, in a manner similar to the embodiments in FIGS. 5 to 8. Also, a structure of the light-blocking wall 47 may correspond to the embodiments in FIGS. 13 to 15.

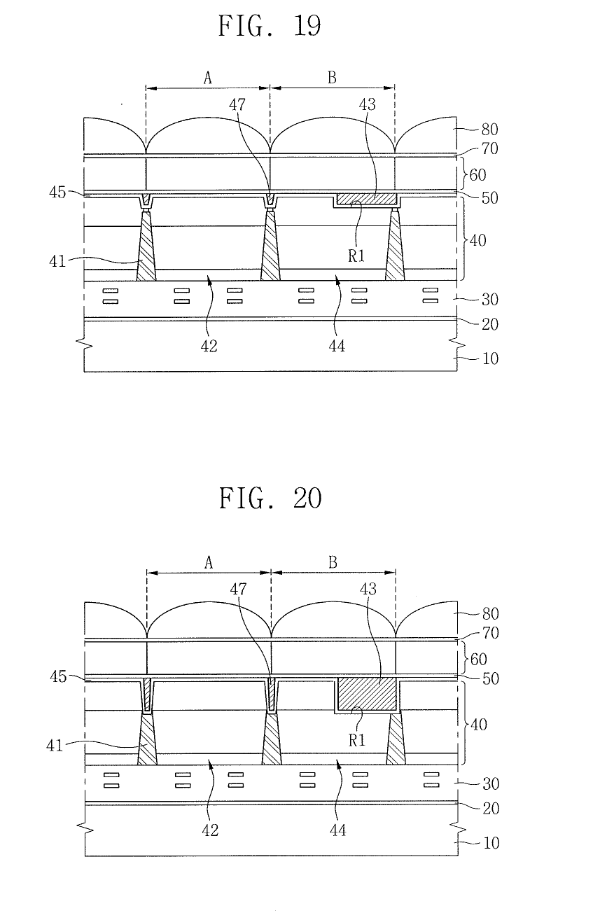

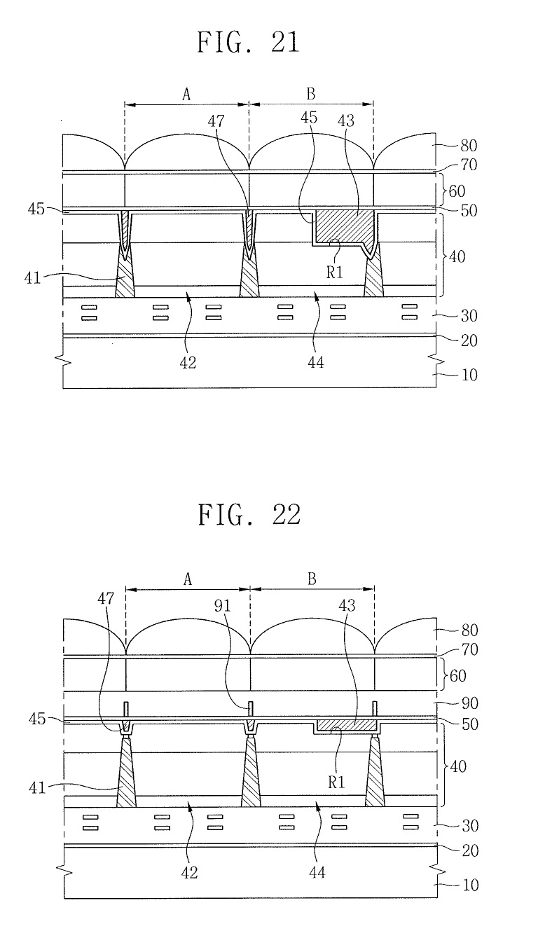

FIGS. 19 to 21 illustrate cross-sectional views of another embodiment of image sensors having another insulating layer. Referring to FIGS. 19 to 21, compared to the embodiments in FIGS. 16 to 18, the image sensor may further include a third insulating layer 45 between a photodiode layer 44 and a first insulating layer 50. The third insulating layer 45 between the photodiode layer 44 and the first insulating layer 50 may be the same material in the same layer as the third insulating layer 45 between the photodiode layer 44 and the light-blocking layer 43. The third insulating layer 45 between the photodiode layer 44 and the first insulating layer 50 may be an oxide layer, for example, HfO₂.

The third insulating layer 45 between the photodiode layer 44 and the first insulating layer 50 may be formed in a manner similar to the embodiments in FIGS. 9 to 12. The third insulating layer 45 between the photodiode layer 44 and the light-blocking layer 43 may be formed in a manner similar to the embodiments of FIGS. 5 to 8.

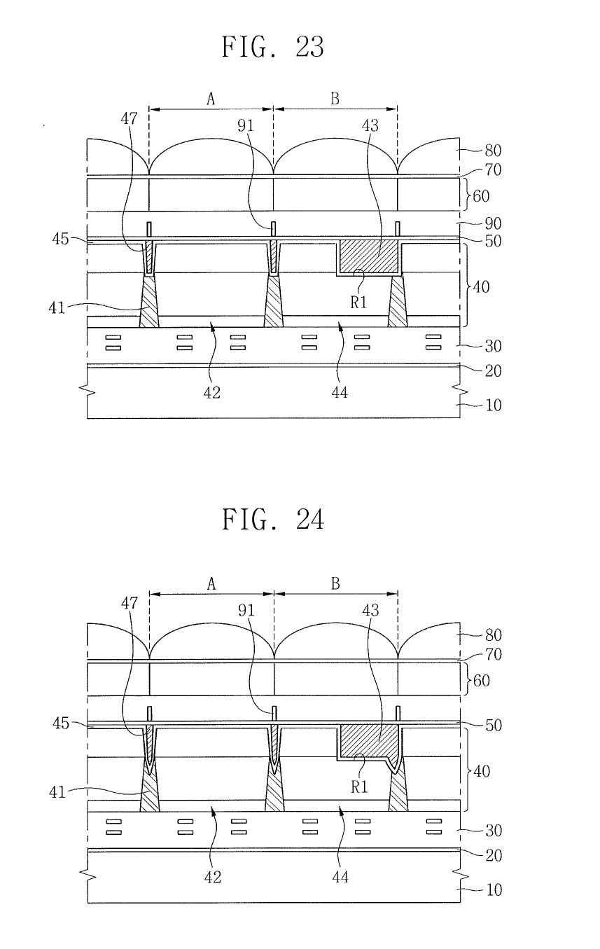

FIGS. 22 to 24 illustrate cross-sectional views of another embodiment of image sensors having an insulating layer and a light-blocking wall. Referring to FIGS. 22 to 24, compared to the embodiments illustrated in FIGS. 19 to 21, the image sensor may further include a fourth insulating layer 90 on a first insulating layer 50. The fourth insulating layer 90 may be formed, for example, of an oxide layer.

The fourth insulating layer 90 may include light-blocking walls 91 thereinside along boundaries of pixels. The light-blocking wall 91 may be formed of a material having a light-blocking or light-reflecting property. The light-blocking wall 91 may partially block light on a phase-difference detection pixel B from being incident on an adjacent image detection pixel A. A light-blocking wall 91 may partially block light on an adjacent image detection pixel A from being incident on a phase-difference detection pixel B.

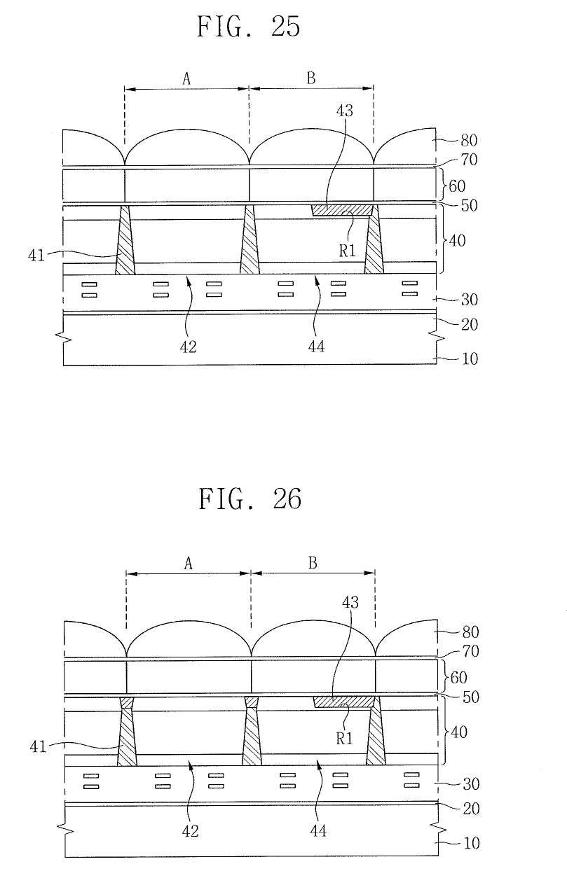

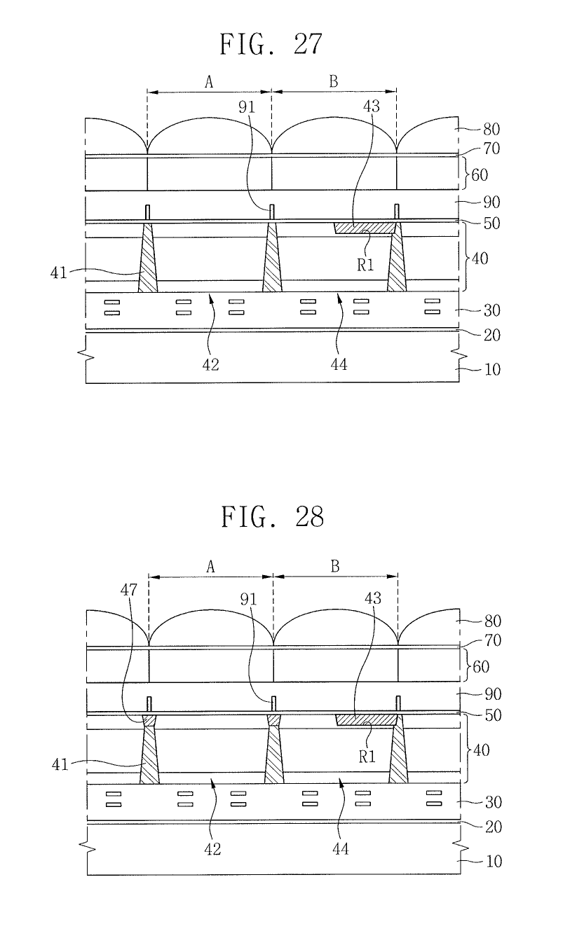

FIGS. 25 to 28 illustrate cross-sectional views of another embodiment of image sensors including a different cell separation wall. Referring to FIGS. 25 to 28, the image sensor includes a cell separation wall 41 that reaches an upper surface of a photodiode layer 44. In a recess R1, there is no insulating layer insulating the photodiode layer 44 from a light-blocking layer 43. Also, as illustrated in FIGS. 26 and 28, a light-blocking wall 47 formed in the photodiode layer 44 may be formed by etching an upper portion of the cell separation wall 41. The light-blocking wall 47 may include a portion of the photodiode layer 44.

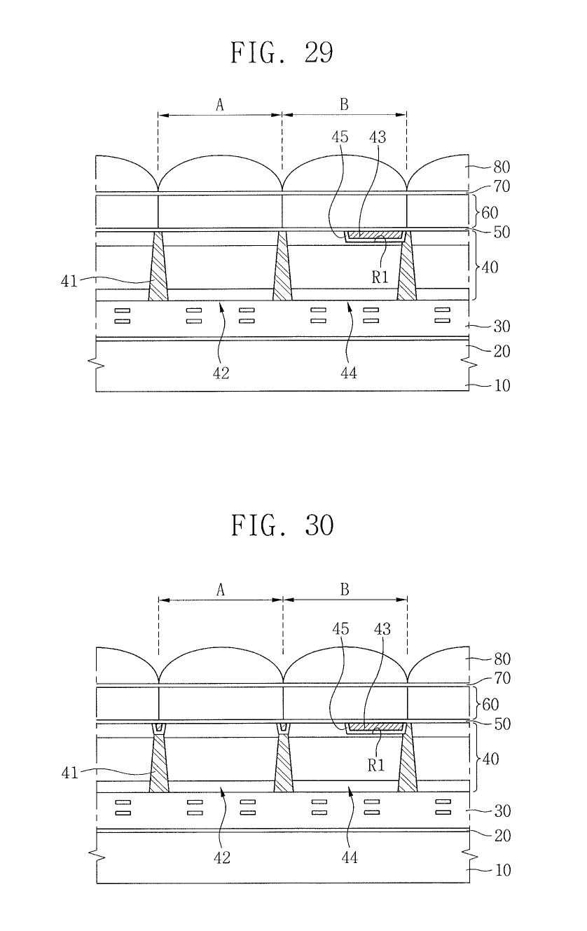

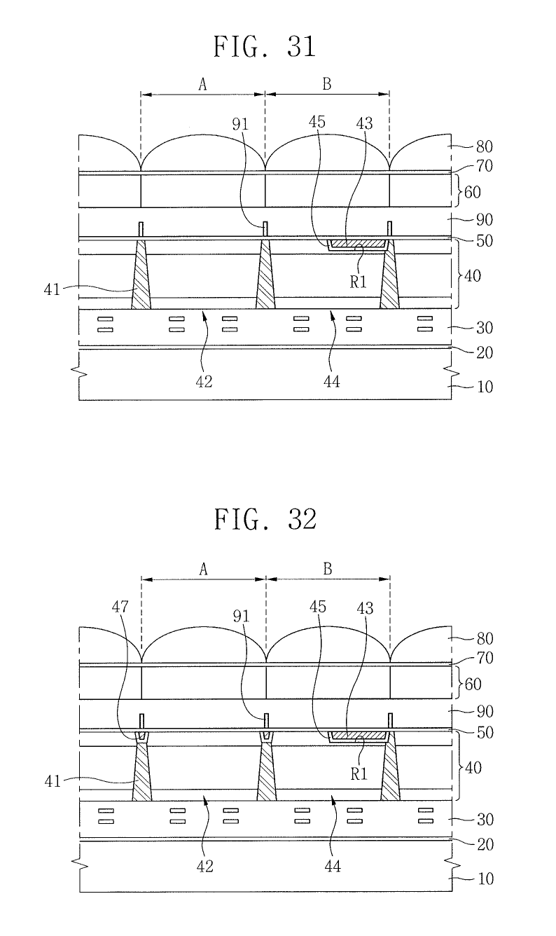

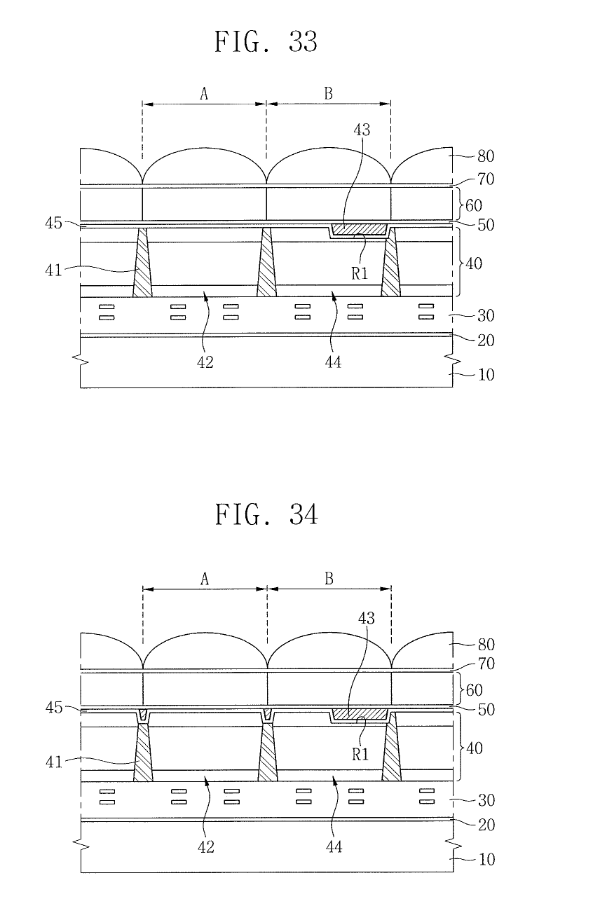

FIGS. 29 to 32 illustrate cross-sectional views of another embodiment of image sensors having an insulating layer. Referring to FIGS. 29 to 32, the image sensor may include a cell separation wall 41 that reaches an upper surface of a photodiode layer 44. A third insulating layer 45 may be formed between the photodiode layer 44 and a light-blocking layer 43 in a recess R1. Also, as illustrated in FIGS. 30 and 32, a light-blocking wall 47 formed in the photodiode layer 44 may be formed by etching an upper portion of the cell separation wall 41. The light-blocking wall 47 may include a portion of the photodiode layer 44.

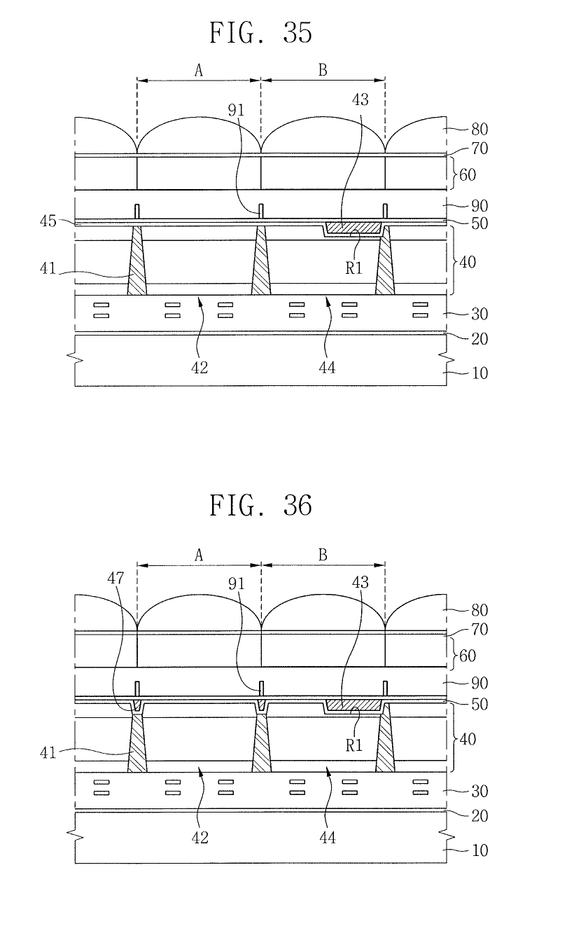

FIGS. 33 to 36 illustrate cross-sectional views of another embodiment of image sensors having another insulating layer. Referring to FIGS. 33 to 36, the image sensor may include a cell separation wall 41 reaching an upper surface of a photodiode layer 40. A third insulating layer 45 may be formed between the photodiode layer 44 and a light-blocking layer 43 in a recess R1. The third insulating layer 45 may also be formed between the photodiode layer 44 and a first insulating layer 50. Also, as illustrated in FIGS. 34 and 36, a light-blocking wall 47 formed in the photodiode layer 44 may be formed by etching an upper portion of the cell separation wall 41. The light-blocking wall 47 may include a portion of the photodiode layer 44.

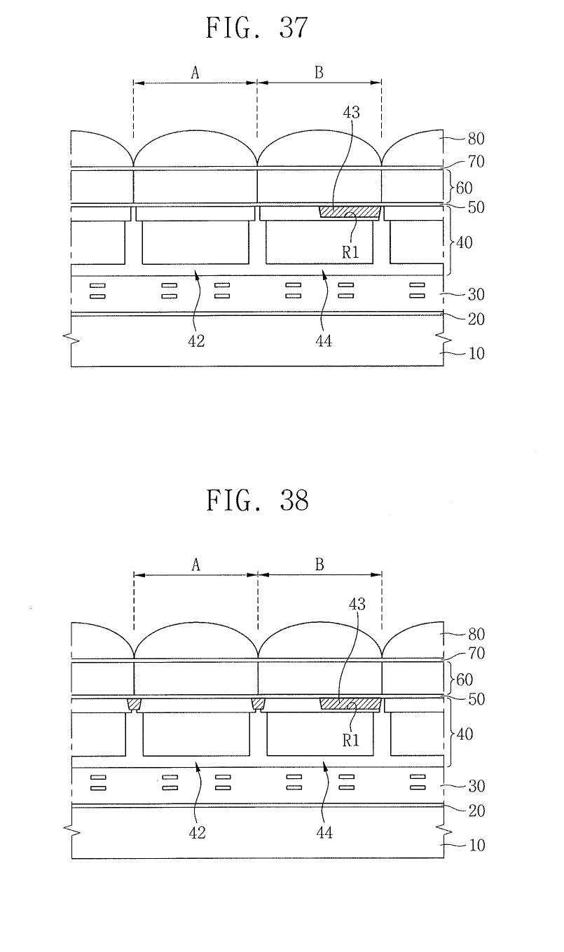

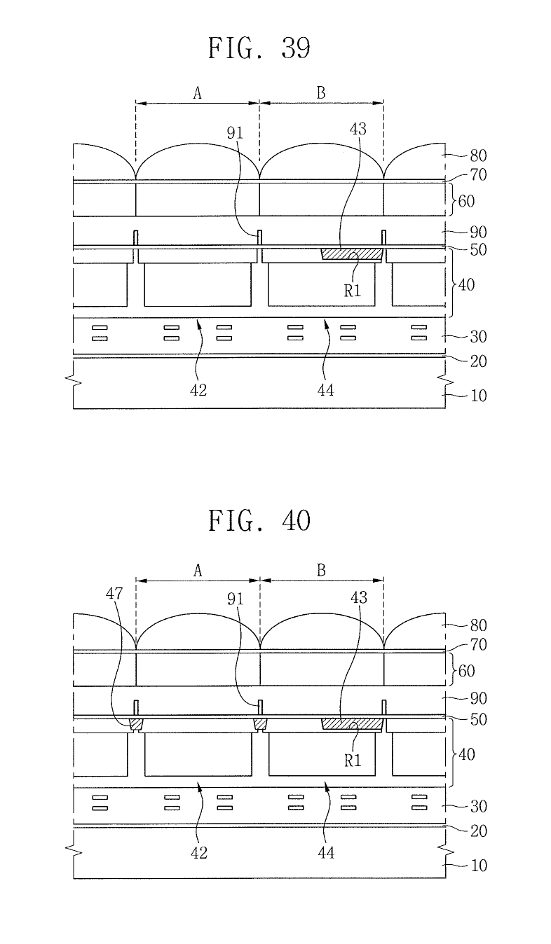

FIGS. 37 to 40 illustrate cross-sectional views of another embodiment of image sensors having no cell separation wall. Referring to FIGS. 37 to 40, the image sensor may not include a cell separation wall in a photodiode layer 44. A cell is functionally separated from other cells by a P-N junction region between a photodiode layer 44 and a semiconductor layer underlying the photodiode layer 44. In the recess R1, there is no insulating layer insulating the photodiode layer 44 and a light-blocking layer 43. Also, as illustrated in FIGS. 38 and 40, a light-blocking wall 47 formed in the photodiode layer 40 may be formed by partially etching a boundary region of the photodiode layer 44.

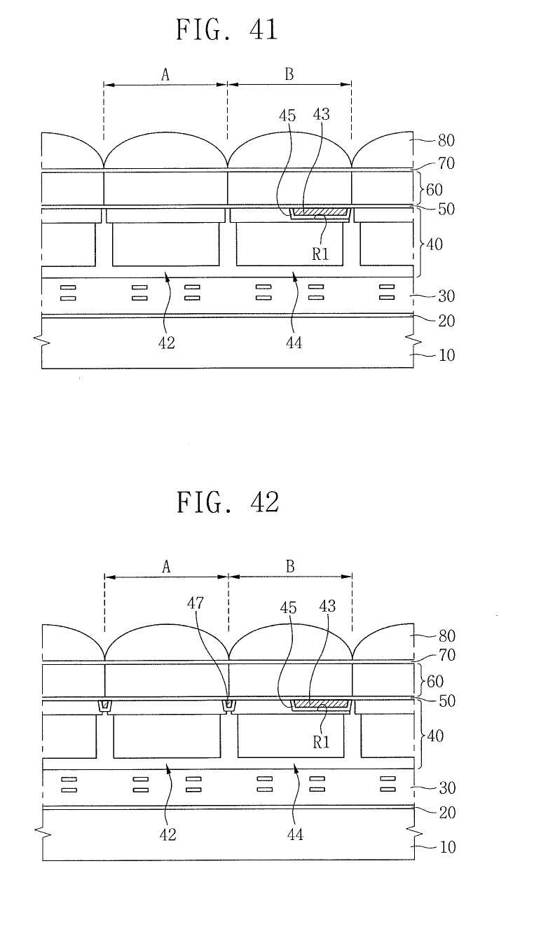

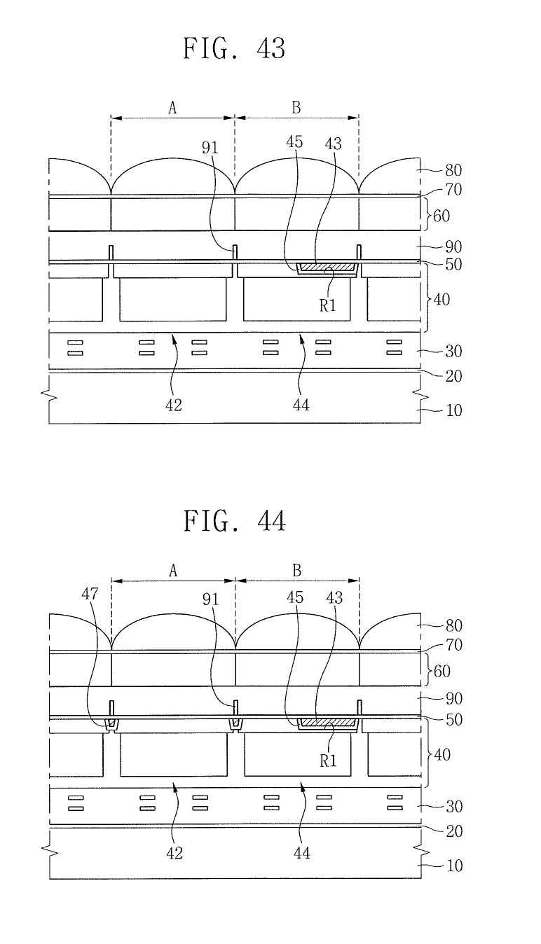

FIGS. 41 to 44 illustrate cross-sectional views of another embodiment of image sensors having an insulating layer. Referring to FIGS. 41 to 44, the image sensor may not include a cell separation wall in a photodiode layer 40. A third insulating layer 45 is formed between the photodiode layer 44 and a light-blocking layer 43 in a recess R1. Also, as illustrated in FIGS. 42 to 44, a light-blocking wall 47 formed in a photodiode layer 40 may be formed by partially etching a boundary region of photodiode layer 44.

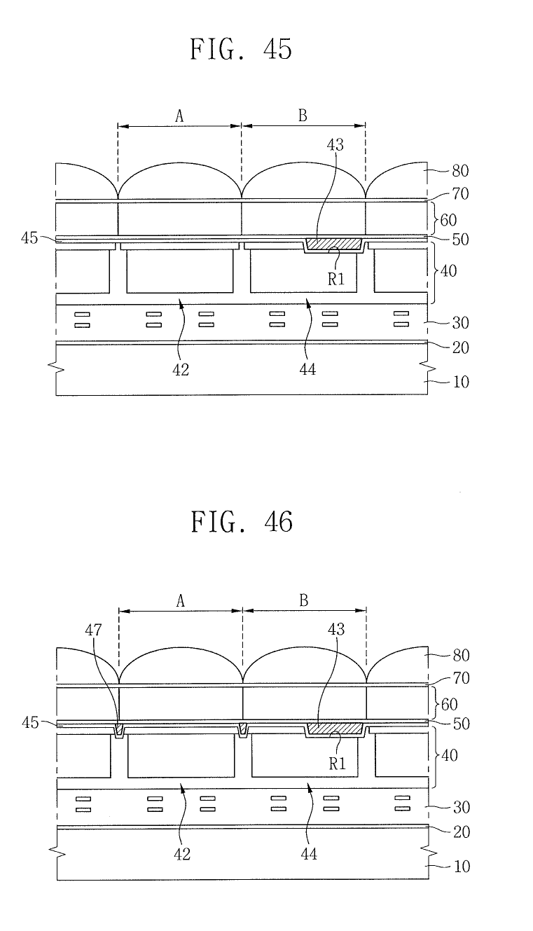

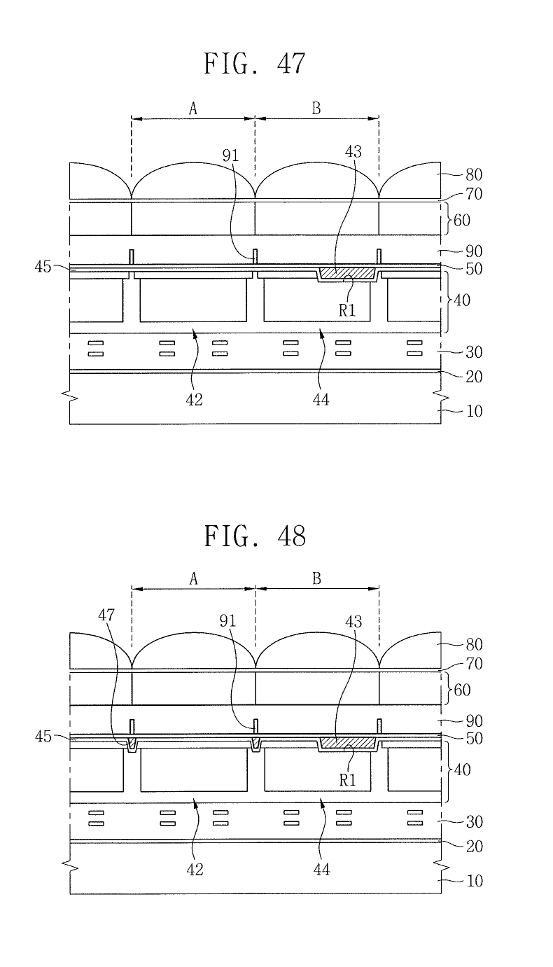

FIGS. 45 to 48 illustrate cross-sectional views of another embodiment of image sensors having another insulating layer. Referring to FIGS. 45 to 48, the image sensor may not include a cell separation wall in a photodiode layer 40. A third insulating layer 45 is formed between the photodiode layer 44 and a light-blocking layer 43 in a recess R1. The third insulating layer 45 may also be formed between the photodiode layer 44 and the first insulating layer 50. Also, as illustrated in FIGS. 46 and 48, a light-blocking wall 47 formed in a photodiode layer 40 may be formed by partially etching a boundary region of the photodiode layer 44.

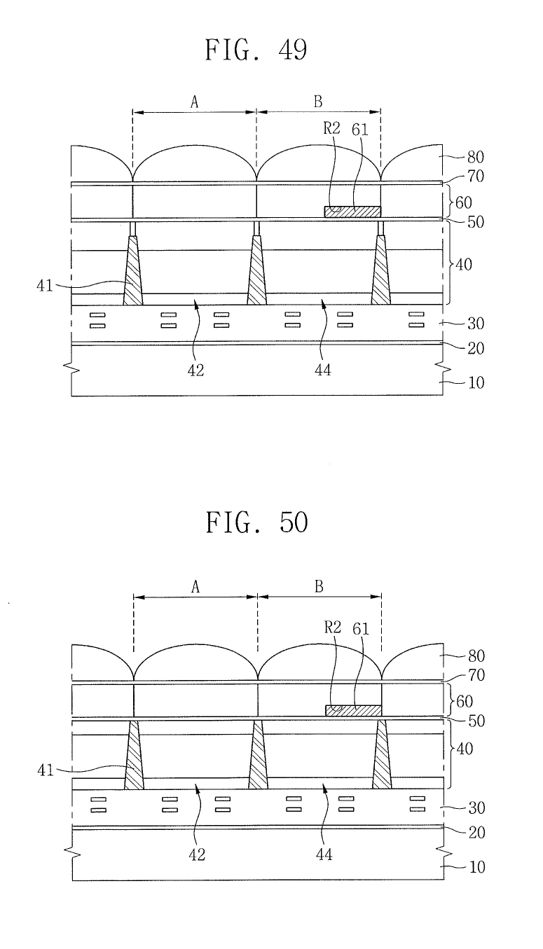

FIG. 49 illustrates a cross-sectional view of another embodiment of an image sensor having a color filter layer with a light-blocking layer. Referring to FIG. 49, the image sensor includes an image detection pixel A and a phase-difference detection pixel B. The image detection pixel A includes a support substrate 10, an adhesive layer 20, a metal interconnection layer 30, a photodiode layer 42, a first insulating layer 50, a color filter layer 60, a light-blocking layer 61, a second insulating layer 70, and a microlens layer 80.

Referring to FIG. 49, the phase-difference detection pixel B has different structures of the photodiode layer 44, the color filter layer 60, and the light-blocking layer 61 from the structures in FIG. 1.

The photodiode layer 44 may include an upper P-region and a center N-region. The photodiode layer 44 may include a cell separation wall 41 at a boundary region with an adjacent image detection pixel A. As illustrated in FIG. 49, an upper end of the cell separation wall 41 may be higher than the N-region and lower than an upper surface of the photodiode layer 44.

The color filter layer 60 may be formed on the first insulating layer 50. The color filter layer 60 may include a recess R2. The recess R2 may be formed to have a predetermined width from an edge of the color filter layer 60 toward the center. The recess R2 may be a trench having a predetermined shape, e.g., rectangular.

According to one example implementation, a short width of the recess R2 may be in the range of 30 to 60% of a width of the color filter layer 60. The recess R2 may have a depth greater than a height of the color filter layer 60. The recess R2 may be surrounded by the color filter layer 60. The recess R2 may be formed to open downward, e.g., in a direction toward the first insulating layer 50. An upper portion of the recess R2 may be covered with the color filter layer 60.

The light-blocking layer 61 may be formed in the recess R2 of the color filter layer 60. The light-blocking layer 61 may be an insulating light-blocking material, for example, a black color filter. Alternatively, the light-blocking layer 61 may use a non-insulating light-blocking material, for example, W.

In a manufacturing process, the first insulating layer 50 may be formed on the photodiode layer 40. The light-blocking layer 61 may be formed in the phase-difference detection pixel B on the first insulating layer 50. The color filter layer 60 may be formed on the light-blocking layer 61 and the first insulating layer 50. The second insulating layer 70 may be formed on the color filter layer 60. The microlens layer 80 may be formed on the second insulating layer 70.

FIG. 50 illustrates a cross-sectional view of another embodiment of an image sensor including a different cell separation wall. Referring to FIG. 50, a cell separation wall 41 of the image sensor reaches an upper surface of a photodiode layer 40. Other components of the embodiment in FIG. 50 may be the same as in the image sensor of FIG. 49.

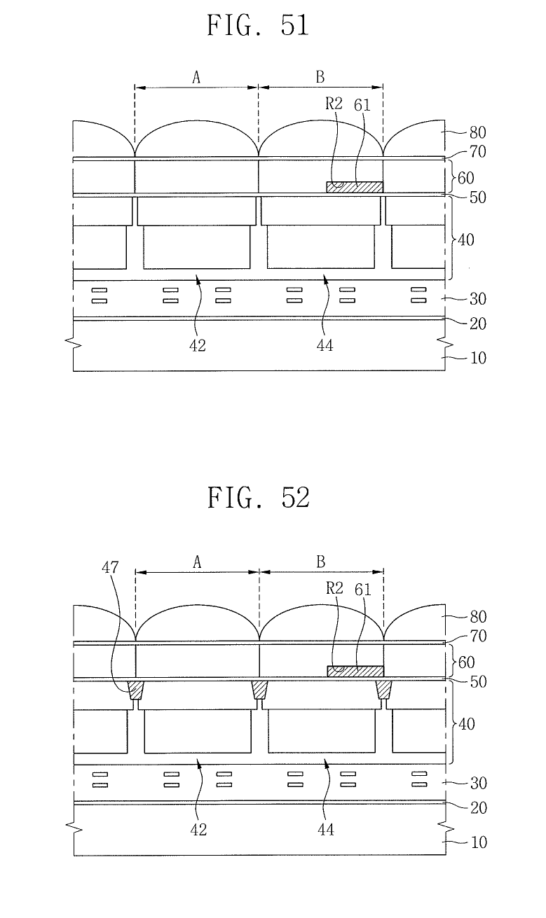

FIG. 51 illustrates a cross-sectional view of another embodiment of an image sensor with no cell separation wall. Referring to FIG. 51, the image sensor may not include a cell separation wall 41 in a photodiode layer 40. Other components of the embodiment in FIG. 51 may be the same as in the image sensor of FIG. 49.

FIGS. 52 to 54 illustrate cross-sectional views of another embodiment of image sensors having a light-blocking wall and an insulating layer. Referring to FIG. 52, the image sensor may not include a cell separation wall 41 in a photodiode layer 40. A light-blocking wall 47 may be formed at boundary regions of photodiode layers 42 and 44. No insulating layer may be formed between the light-blocking wall 47 and the photodiode layers 42 and 44. The light-blocking wall 47 may be formed, for example, of an insulating material.

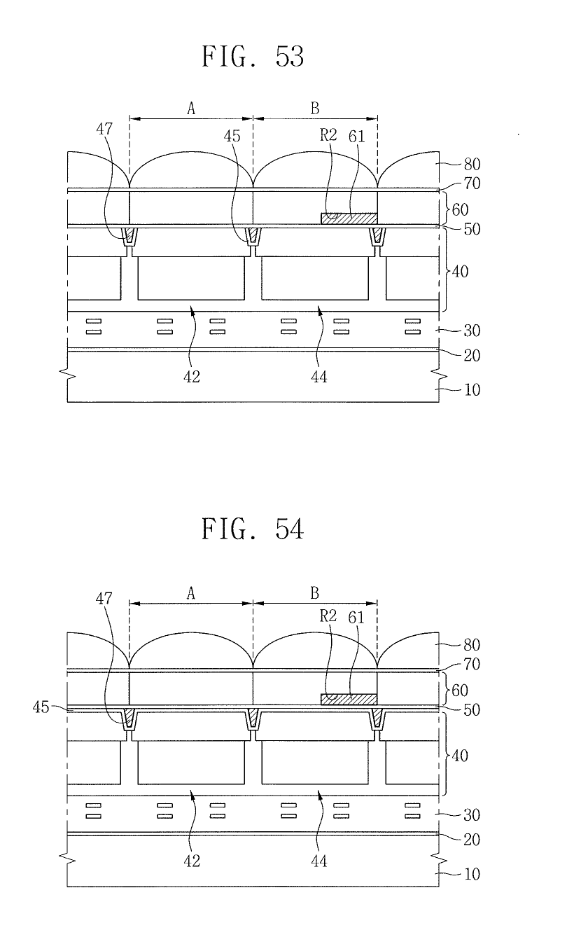

Referring to FIG. 53, the image sensor may not include a cell separation wall 41 in a photodiode layer 40. A light-blocking wall 47 may be formed in boundary regions of photodiode layers 42 and 44. A third insulating layer 45 may be formed between the light-blocking wall 47 and the photodiode layers 42 and 44. The light-blocking wall 47 may be formed of an insulating material or a non-insulating material.

Referring to FIG. 54, the image sensor may not include a cell separation wall in a photodiode layer 40. A light-blocking wall 47 may be formed in boundary regions of photodiode layers 42 and 44. A third insulating layer 45 may be formed between the light-blocking wall 47 and the photodiode layers 42 and 44. The light-blocking wall 47 may be formed of an insulating material or a non-insulating material. The third insulating layer 45 may be formed between the photodiode layer 40 and a first insulating layer 50.

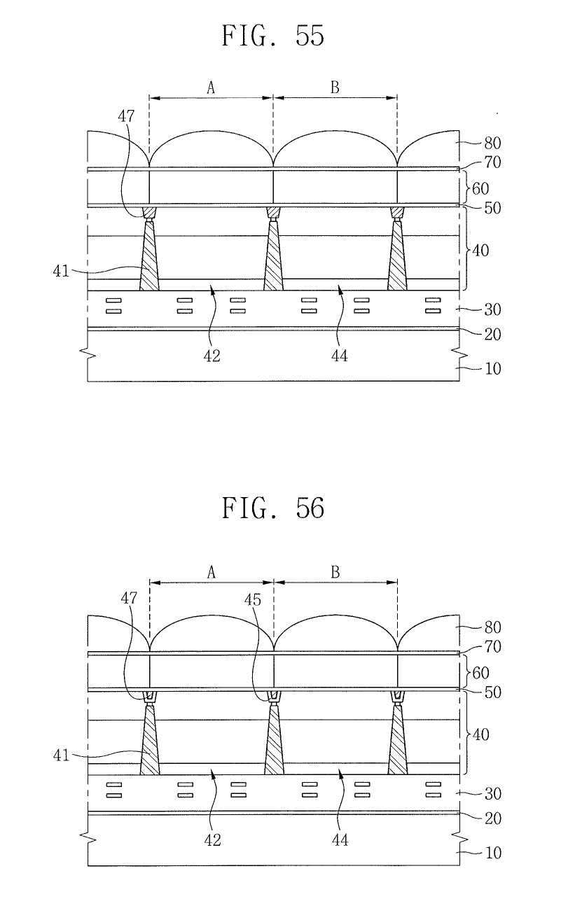

FIGS. 55 to 57 illustrate cross-sectional views of another embodiment of image sensors having a cell separation wall, a light-blocking wall, and an insulating layer. Referring to FIG. 55, the image sensor may include a cell separation wall 41 in a photodiode layer 40. A photodiode layer 40 and a color filter layer 60 may not include a light-blocking layer. A light-blocking wall 47 may be formed at a boundary region of photodiode layers 42 and 44. There is no insulating layer between the light-blocking wall 47 and the photodiode layers 42 and 44. The light-blocking wall 47 may be formed, for example, of an insulating material.

Referring to FIG. 56, the image sensor may include a cell separation wall 41 in a photodiode layer 40. A photodiode layer 40 and a color filter layer 60 may not include a light-blocking layer. A light-blocking wall 47 may be formed in a boundary region of photodiode layers 42 and 44. A third insulating layer 45 may be formed between the light-blocking wall 47 and the photodiode layers 42 and 44. The light-blocking wall 47 may be formed of an insulating material or a non-insulating material.

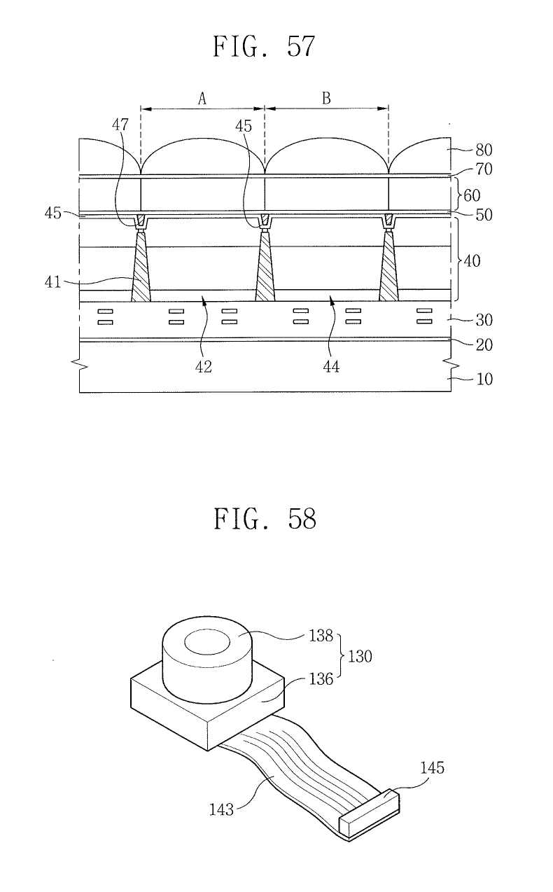

Referring to FIG. 57, the image sensor may include a cell separation wall 41 in a photodiode layer 40. A photodiode layer 40 and a color filter layer 60 may not include a light-blocking layer. A light-blocking wall 47 may be formed at a boundary region of photodiode layers 42 and 44. A third insulating layer 45 may be formed between the light-blocking wall 47 and the photodiode layers 42 and 44. The light-blocking wall 47 may be formed of an insulating material or a non-insulating material. The third insulating layer 45 may also be formed between the photodiode layer 40 and a first insulating layer 50.

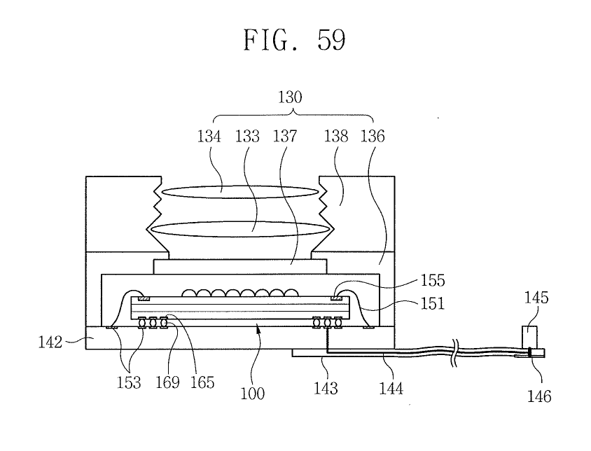

FIGS. 58 and 59 illustrate an embodiment of a camera module including an image sensor in accordance any one of the aforementioned embodiments. Referring to FIGS. 58 and 59, the camera module includes a case 130, printed circuit boards 142 and 143, and a image sensor 100.

The case 130 includes a sensor case 136 and a lens holder 138. The sensor case 136 includes a light-transmitting window 137. The sensor case 136 may be mounted on a first printed circuit board 142. The lens holder 138 may be mounted on the sensor case 136. The lens holder 138 may include first and second lenses 133 and 134. A second printed circuit board 143 may be connected to a surface of the first printed circuit board 142. External terminals 145 and 146 may be connected to an end of the second printed circuit board 143.

The image sensor 100 may be mounted on the first printed circuit board 142. The image sensor 100 may include a support substrate, a photodiode layer, an insulating layer, and a color filter layer. The image sensor 100 may include input/output pads 155 and 165 and contact devices 169. Microlens layers of the image sensor 100 may be aligned to the light-transmitting window 137.

The contact devices 169 may be connected to bond fingers 153 formed in the first printed circuit board 142. The upper input/output pads 155 may be connected to the bond fingers 153 through connection devices 151. The bond fingers 153 may be electrically connected to the external terminals 145 and 146 via an internal interconnection 144 in the first printed circuit board 142 and the second printed circuit board 143. The external terminals 145 and 146 may include a multi-connector 145 and/or multi-tap 146. In other embodiments, the second printed circuit board 143 may be omitted. The first printed circuit board 142 may include other external terminals, such as a ball grid array (BGA), a lead grid array (LGA), a pin grid array (PGA), or a combination thereof.

The first printed circuit board 142 and the second printed circuit board 143 may include a rigid printed circuit board, a flexible printed circuit board, or a rigid-flexible printed circuit board. For example, the first printed circuit board 142 may be a rigid printed circuit board, and the second printed circuit board 143 may be a flexible printed circuit board. The contact devices 169 may include, for example, a conductive bump, a solder ball, an anisotropic conductive paste (ACP), an anisotropic conductive film (ACF), a non-conductive paste (NCP), a non-conductive film (NCF), or a combination thereof. The connection devices 151 may include, for example, a bonding wire, a beam lead, a conductive tape, or a combination thereof.

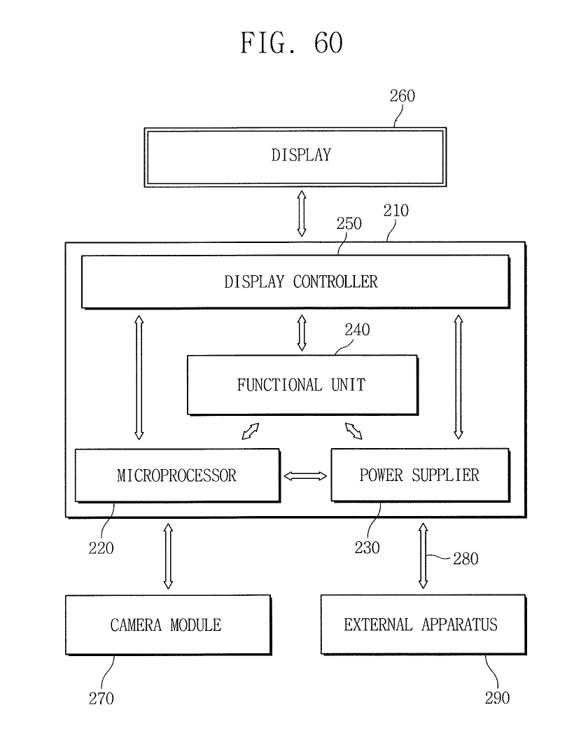

FIG. 60 illustrates an embodiment of an electronic apparatus including an image sensor in accordance with any of the aforementioned embodiments. Referring to FIG. 60, the image sensor may be applied to an electronic system. The electronic system may include a body 210, a microprocessor 220, a power supplier 230, a functional unit 240, and a display controller 250. The body 210 may be a motherboard including a printed circuit board (PCB). The microprocessor 220, the power 230, the functional unit 240, and the display controller 250 may be mounted on the body 210. A display 260 and/or a camera module 270 may be mounted inside or outside of the body 210. For example, the display 260 may be mounted on a surface of the body 210 to display an image processed by the display controller 250.

The power supplier 230 may receive a constant voltage from a power source (e.g., a battery), divide the voltage into required voltage levels, and supply those voltages to the microprocessor 220, the functional unit 240, and the display controller 250. The microprocessor 220 may receive a voltage from the power supplier 230 to control the functional unit 240 and the display 260.

The functional unit 240 may perform various functions of the electronic system. For example, when the electronic system is a mobile phone, the functional unit 240 may have several components which perform functions of the mobile phone such as dialing, video output to the display 260 through communication with an external apparatus 290, and sound output to a speaker, and may function as a camera image processor.

In one embodiment, when the electronic system is connected to a memory card, or other storage device or medium, to expand storage capacity, The functional unit 240 may be a memory card controller, and may exchange signals with the external apparatus 290 through a wired or wireless communication unit 280. When the electronic system has a Universal Serial Bus (USB) interface used to expand functionality, the functional unit 240 may function as an interface controller.

The image sensor including a phase-difference detection pixel in accordance with embodiments described herein may be applied to various multimedia devices having image shooting functions. Examples include a digital camera, a mobile phone, a smart phone, a tablet PC, a smart table PC, a laptop computer, a TV, and a smart TV.

In accordance with one or more of the aforementioned embodiments, performance of an image detection pixel and a phase-difference detection pixel may be optimized at the same time by adjusting light focal points of the image detection pixel and the phase-difference detection pixel, which configure an image sensor, on the same plane or almost the same plane.

In accordance with these or other embodiments, the heights of an image detection pixel and a phase-difference detection pixel, which configure an image sensor, may be lowered by burying a light-blocking wall in a photodiode layer. Accordingly, the image sensor may be reduced in size.

According to these or other embodiments, efficiency of an image detection pixel or a phase-difference detection pixel, which configure an image sensor, may be improved by forming a light-blocking wall in a boundary region of a photodiode layer.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

1. A phase-difference detection pixel, comprising:
a substrate;
a photodiode layer on the substrate and partially including an upwardly open recess;
a light-blocking layer in the recess;
a first insulating layer on the photodiode layer and the light-blocking layer;
a color filter layer on the first insulating layer; and
a microlens layer on the color filter layer.

2. The pixel as claimed in claim 1, further comprising:
a second insulating layer between the light-blocking layer and an interior of the recess.

3. The pixel as claimed in claim 2, wherein the light-blocking layer and the photodiode layer have upper surfaces at substantially a same level.

4. The pixel as claimed in claim 2, wherein the second insulating layer is between the photodiode layer and the first insulating layer.

5. The pixel as claimed in claim 1, wherein the photodiode layer has an edge region that includes a light-blocking wall.

6. The pixel as claimed in claim 1, further comprising:
a third insulating layer between the first insulating layer and the color filter layer; and
a light-blocking wall along a boundary region of a pixel in the third insulating layer.

7. The pixel as claimed in claim 1, wherein the light-blocking layer reaches a boundary region of an adjacent cell.

8. The pixel as claimed in claim 7, wherein:
the photodiode layer includes a cell separation wall, and the light-blocking layer reaches the cell separation wall.

9. The pixel as claimed in claim 8, wherein the light-blocking layer is deeper in the cell separation wall than in the photodiode layer.

10. The pixel as claimed in claim 1, wherein:
the photodiode layer includes an N-region and a P-region, and the recess is in the P-region.

11. The pixel as claimed in claim 1, wherein:
the photodiode layer includes an N-region and a P-region, and the recess reaches a portion of the N-region.

12. A phase-difference detection pixel, comprising:
a substrate;
a metal interconnection layer on the substrate;
a photodiode layer on the metal interconnection layer;
a first insulating layer on the photodiode layer;
a color filter layer on the first insulating layer;
a light-blocking layer in the color filter layer; and
a microlens layer on the color filter layer.

13. The pixel as claimed in claim 12, wherein the light-blocking layer opens in a direction toward a bottom of the color filter layer.

14. The pixel as claimed in claim 12, wherein the light-blocking layer includes a black color filter.

15. The pixel as claimed in claim 12, further comprising:
a second insulating layer between the first insulating layer and the color filter layer; and
a light-blocking wall along a boundary region of a pixel in the second insulating layer.

16. An apparatus, comprising:
an image detection pixel;
a phase-difference detection pixel; and
wall between the image detection pixel and the phase-difference pixel,
wherein the image detection pixel includes a first region of a photodiode layer and the phase-difference pixel includes a second region of the photodiode layer, and wherein the second region of the photodiode layer includes a light-blocking layer not included in the first region.

17. The apparatus as claimed in claim 16, wherein the light-blocking layer is in a recess in the second region of the photodiode layer.

18. The apparatus as claimed in claim 16, wherein the wall is between the first region and the second region of the photodiode layer.

19. The apparatus as claimed in claim 16, further comprising:
an insulating layer between the light-blocking layer and the photodiode layer in the second region.

20. The apparatus as claimed in claim 16, wherein a bottom surface of the light-blocking layer is lower than an upper surface of the wall.
